(19) United States
(12) Patent Application Publication
(10) Pub. No.: US 2025/0259825 A1
(43) Pub. Date: Aug. 14, 2025

(54) PLASMA PROCESSING APPARATUS, PLASMA PROCESSING METHOD, AND REMOTE PLASMA SOURCE

(71) Applicant: Tokyo Electron Limited, Tokyo (JP)

(72) Inventor: Jun YAMAWAKU, Yamanashi (JP)

(21) Appl. No.: 18/857,282

(22) PCT Filed: Apr. 13, 2023
(86) PCT No.: PCT/JP2023/015000

§ 371 Date: Oct. 16, 2024

(30) Foreign Application Priority Data
Apr. 26, 2022 (JP) 2022-072161

(51) Int. Cl. H01J 37/32; C23C 16/507

(52) U.S. Cl. CPC H01J 37/32357; C23C 16/507; H01J 37/3211; H01J 37/32541; H01J 2237/332

(57) ABSTRACT

This plasma processing device is provided with: a chamber; a substrate support unit provided in the chamber; a remote plasma source which is provided outside the chamber to generate a remote plasma; and a plasma introduction unit which introduces the remote plasma generated by the remote plasma source into the chamber. The remote plasma source comprises: a plasma generation container that has an annular internal space in which a plasma is generated; a gas supply unit that supplies a gas to the plasma generation container; a pair of opposed electrodes that are provided annularly along the annular space of the plasma generation container; an on/off switchable high-frequency power supply for forming a high-frequency electric field between the pair of electrodes; and a coil which is provided spirally around the plasma generation container, and to which a high-frequency current is supplied to form a looped magnetic field between the pair of electrodes.

### TECHNICAL FIELD

The present disclosure relates to a plasma processing apparatus, a plasma processing method, and a remote plasma source.

### BACKGROUND

It is known in the manufacturing process of semiconductor devices that a plasma processing apparatus is used to perform a plasma processing on a semiconductor wafer which is a substrate, and magnetism is used for the plasma processing apparatus. For example, Patent Document 1 discloses that a plasma chamber may be a toroidal loop defined as forming a loop internal plasma channel having a closed path to maintain plasma current circulation in a closed circuit. Also, Patent Document 2 discloses a technology related to a plasma reactor having an electron beam source with no inherent asymmetry, in which frequencies of multiple power generators are optimized and applied to a space from an upper electrode to generate capacitively coupled plasma, and at this time, a magnetic field is generated by a coil to enhance the plasma density. Further, Patent Document 3 discloses a vertical batch-type processing apparatus in which an annular plasma space is divided into a plurality of zones, and gas is discharged and exhausted. In the vertical batch-type processing apparatus, capacitively coupled plasma can be formed in the plasma space which can be used as remote plasma, and the center of the top plate is made of quartz to allow the magnetic field of a coil to pass therethrough.

### PRIOR ART DOCUMENT

### Patent Document

Patent Document 1: Japanese National Publication of International Patent Application No. 2021-530616
Patent Document 2: Japanese Patent Laid-Open Publication No. 2021-153056
Patent Document 3: Japanese Patent Laid-Open Publication No. 2013-206732

### SUMMARY OF THE INVENTION

### Problem to be Solved

The present disclosure provides a technique for generating high-density remote plasma capable of being turned ON/OFF at a high speed, and performing a plasma processing on a substrate.

### Means to Solve the Problem

A plasma processing apparatus according to one aspect of the present disclosure includes: a chamber; a substrate support provided within the chamber to support a substrate; a remote plasma source provided outside the chamber to generate remote plasma; and a plasma introduction section that introduces the remote plasma generated by the remote plasma source, into the chamber. The remote plasma source includes: a plasma generating container having an annular space inside, in which plasma is generated in the space; a gas supply unit that supplies gas to the plasma generating container; a pair of facing electrodes annularly provided along the annular space of the plasma generating container; a radio-frequency power source capable of being turned ON/OFF to form a radio-frequency electric field between the pair of electrodes; and a coil that is spirally provided around the plasma generating container and is supplied with a radio-frequency current to form a loop-shaped magnetic field between the pair of electrodes.

### Effect of the Invention

According to the present disclosure, provided is a technique for generating high-density remote plasma capable of being turned ON/OFF at a high speed, and performing a plasma processing on a substrate.

### BRIEF DESCRIPTION OF THE DRAWINGS

FIG. 1 is a cross-sectional view schematically illustrating a plasma processing apparatus according to one embodiment.

FIG. 2 is a perspective view illustrating the appearance of a remote plasma source in the plasma processing apparatus of FIG. 1.

FIG. 3 is a perspective view for explaining the principle of the remote plasma source in the plasma processing apparatus of FIG. 1.

FIG. 4 is a cross-sectional view for explaining the principle of the remote plasma source in the plasma processing apparatus of FIG. 1.

FIG. 5 is a cross-sectional view illustrating a modification of a plasma introduction section.

FIG. 6 is a view illustrating the technology of Patent Document 1 corresponding to the remote plasma source of the present embodiment.

### DETAILED DESCRIPTION TO EXECUTE THE INVENTION

Hereinafter, an embodiment will be described with reference to accompanying drawings.

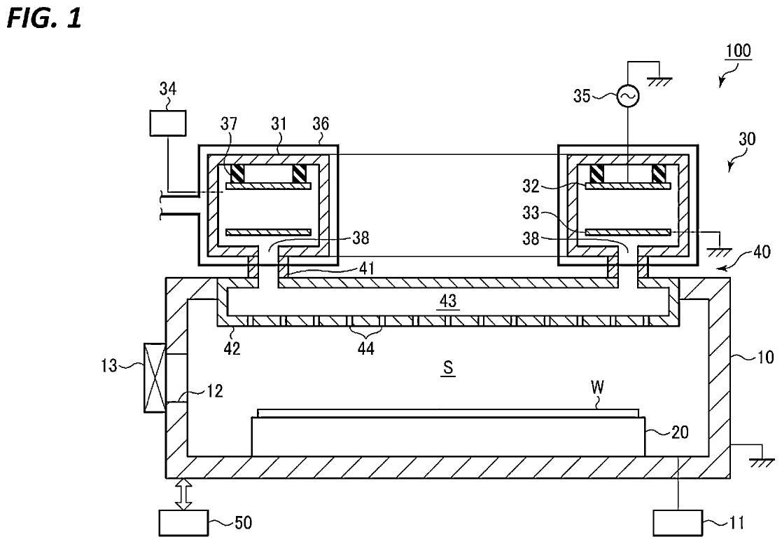

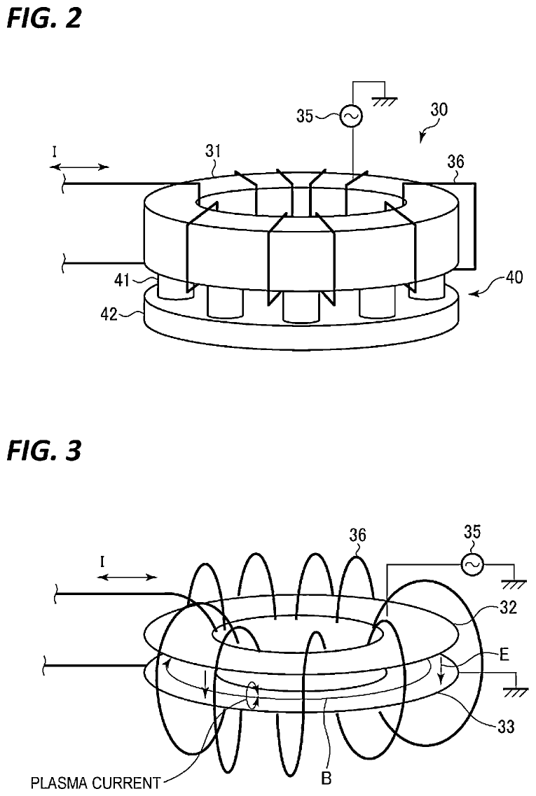

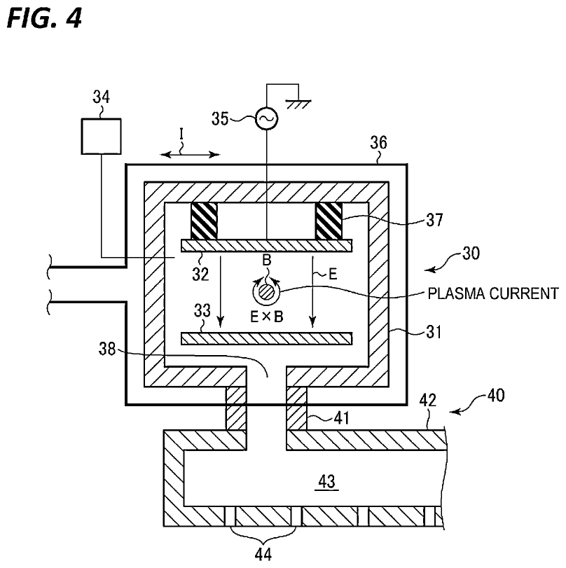

FIG. 1 is a cross-sectional view schematically illustrating a plasma processing apparatus according to one embodiment, FIG. 2 is a perspective view illustrating the appearance of a remote plasma source in the plasma processing apparatus of FIG. 1, and FIG. 3 and FIG. 4 are a perspective view and a cross-sectional view for explaining the principle of the remote plasma source in the plasma processing apparatus of FIG. 1.

A plasma processing apparatus 100 of the present embodiment performs a plasma processing on a substrate W. The plasma processing is not particularly limited, but film forming processing, particularly, the plasma enhanced atomic layer deposition (PEALD), is exemplified as a suitable one. The substrate W is not particularly limited, but a semiconductor wafer is exemplified.

The plasma processing apparatus 100 includes a chamber 10, a substrate support unit 20, a remote plasma source 30, a plasma introduction section 40, and a control unit 50.

The chamber 10 is substantially cylindrical, and is made of metal, for example, metal such as aluminum whose surface is anodized. An exhaust device 11 is connected to the bottom of the chamber 10 to exhaust the inside of the chamber 10, and to adjust the pressure in the chamber 10 to a desired vacuum atmosphere. Also, a loading/unloading port 12 for loading/unloading the substrate W is formed in the side wall of the chamber 10, and the loading/unloading port 12 is capable of being opened/closed by a gate valve 13.

The substrate support unit 20 is provided at the bottom in the chamber 10, and the substrate W is supported (placed) on the top surface of the substrate support unit 20. The substrate support unit 20 is provided with an elevating pin (not illustrated) that moves up and down while protruding or retreating from the surface of the substrate support unit 20 so that the substrate W is transferred. Also, the substrate support unit 20 may be provided with an electrostatic chuck for electrostatically attracting the substrate W, and a temperature control mechanism such as a heater.

The remote plasma source 30 includes a plasma generating container 31, a first electrode 32 and a second electrode 33 facing each other, a gas supply unit 34, a radio-frequency power source 35, and a coil 36.

The plasma generating container 31 is made of a non-magnetic metal, for example, aluminum, and is provided at a position above the chamber 10 corresponding to the outer periphery of the substrate W near the chamber 10. The plasma generating container 31 has an annular space inside, and plasma is generated in the space. When the plasma generating container 31 is made of aluminum, its surface may be anodized. A plurality of holes 38 is formed in the bottom of the plasma generating container 31.

The first electrode 32 and the second electrode 33 are annularly provided along the annular space in the plasma generating container 31, and constitute a pair of electrodes facing each other. In the example of FIG. 1, the first electrode 32 becomes an upper electrode, and the second electrode 33 becomes a lower electrode. An insulating member 37 is provided between the first electrode 32 and the ceiling wall of the plasma generating container 31.

The gas supply unit 34 supplies a plasma gas, which is a gas for generating plasma, into the plasma generating container 31. The plasma gas is not particularly limited, and for example, any one of Ar gas, H₂ gas, N₂ gas, and NH₃ gas, or a mixture of these gases may be used. A gas other than the plasma gas may be supplied from the gas supply unit 34. As such a gas, a pressure regulation gas, a purge gas, or a processing gas for a plasma processing may be exemplified. In this case, the processing gas may or may not be formed into plasma. Also, the plasma gas may be used as a purge gas. The purge gas or the processing gas may be supplied from a gas supply unit separate from the gas supply unit 34.

The radio-frequency power source 35 is for forming a radio-frequency electric field between the first electrode 32 and the second electrode 33, and can be turned ON/OFF. In FIG. 1, radio-frequency power is supplied from the radio-frequency power source 35 to the first electrode 32, and the second electrode 33 is grounded, but the present disclosure it not limited thereto. Radio-frequency power may be supplied to the second electrode 33. The frequency of the radio-frequency supplied from the radio-frequency power source 35 may be 450 kHz to 60 MHz.

As illustrated in FIG. 2, the coil 36 is formed by spirally winding a coil wire around the annular plasma generating container 31. As illustrated in FIG. 3 and FIG. 4, a loop-shaped magnetic field B passing through the center of the coil 36 is induced by supplying a radio-frequency current I from a radio-frequency power source (not illustrated). Since the coil wire constituting the coil 36 is wound around the plasma generating container 31, the loop-shaped magnetic field B may be formed between and along the first electrode 32 and the second electrode 33 in the plasma generating container 31. By adjusting the arrangement of the coil 36, the position of the loop-shaped magnetic field between the first electrode 32 and the second electrode 33 may be adjusted. Here, the strength of the magnetic field B is not particularly limited and may be appropriately set. For example, it may be 30 G or more.

A plasma gas is supplied from the gas supply unit 34 into the plasma generating container 31, and as illustrated in FIG. 3 and FIG. 4, in a state where the loop-shaped magnetic field B is formed by the coil 36 between the first electrode 32 and the second electrode 33, radio-frequency power is supplied from the radio-frequency power source 35. Accordingly, in the presence of the loop-shaped magnetic field B, a radio-frequency electric field E is formed between the first electrode 32 and the second electrode 33, and capacitively coupled plasma is generated. Then, the plasma current (induced current) flows in a circular motion around the loop-shaped magnetic field B, and electrons in the plasma are concentrated in the plasma space by E×B drift, thereby generating high-density plasma in the plasma generating container 31. The generated plasma is guided downward from the holes 38 in the bottom. Here, the second electrode 33 may be formed of punched metal so that plasma can easily pass therethrough.

The plasma introduction section 40 includes a plasma flow path 41, and a shower head 42. The plasma flow path 41 is connected to the hole 38 formed in the bottom of the plasma generating container 31, and guides the plasma from the plasma generating container 31 toward the chamber 10. The shower head 42 discharges the plasma to a processing space S in the chamber 10 when the plasma is guided from the plasma flow path 41. The shower head 42 has a diffusion portion 43 inside and a plurality of discharge holes 544 formed at the bottom. Although the plasma generated in the plasma generating container 31 includes ions and radicals, the ions may be suppressed by colliding with the inner walls of the flow paths while passing through the flow paths 41 and the discharge holes 44 of the shower head 42. Thus, radicals are mainly introduced into the processing space S.

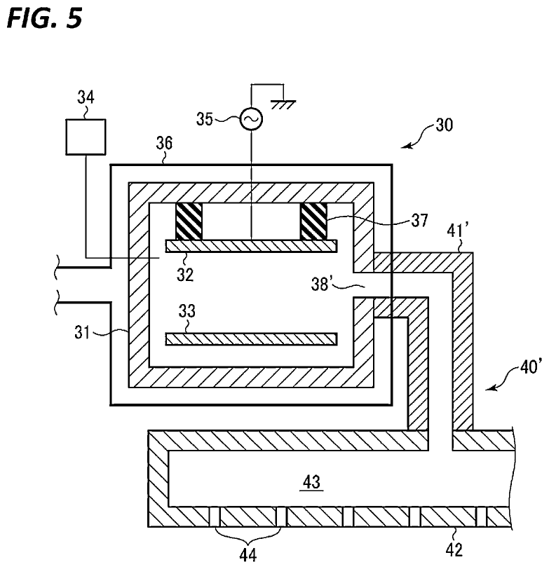

As illustrated in FIG. 5, an introduction section 40′ may have a plasma flow path 41′ connected to a hole 38′ formed on the side of the plasma generating container 31 instead of the plasma flow path 41.

In the remote plasma source 30, in a state where the magnetic field B is always formed by the coil 36 in the plasma generating container 31, an ON/OFF control may be performed on the radio-frequency power source 35 in accordance with gas introduction so that the plasma in the plasma generating container 31 may be turned ON/OFF at a high speed. This makes it possible to quickly supply the radicals generated in the plasma generating container 31 to the processing space S and to cut off the supplying.

The control unit 50 controls components of the plasma processing apparatus 100, such as the exhaust device 11, the gas supply unit 34 and the radio-frequency power source 35 of the remote plasma source 30, and the radio-frequency power source (not illustrated) that supplies a radio-frequency current to the coil 36. The control unit 50 includes a main controller having a CPU, an input device, an output device, a display device, and a storage device. Then, the processing of the plasma processing apparatus 100 is controlled on the basis of the processing recipe stored in a storage medium of the storage device.

Descriptions will be made on the operation of the plasma processing apparatus 100 configured as described above.

First, the substrate W is carried into the chamber 10 and is placed on the substrate support unit 20. Then, gas is supplied into the chamber 10 while the exhaust device 11 exhausts the inside of the chamber 10 to adjust the pressure. Then, a desired vacuum atmosphere is obtained.

Next, plasma is generated by the remote plasma source 30, and the plasma is introduced to the chamber 10 via the plasma introduction section 40. Then, a plasma processing is performed on the substrate W disposed in the chamber 10.

In generating remote plasma by the remote plasma source 30, the loop-shaped magnetic field B passing through the center of the coil 36 is formed by supplying the radio-frequency current I to the coil wire spirally wound around the annular plasma generating container 31. The loop-shaped magnetic field B is formed between the first electrode 32 and the second electrode 33.

In this state, a plasma gas is supplied into the plasma generating container 31 from the gas supply unit 34 and radio-frequency power is supplied from the radio-frequency power source 35 to the first electrode 32 so that the radio-frequency electric field E is formed between the first electrode 32 and the second electrode 33. Accordingly, the plasma gas is excited by the radio-frequency electric field E in the plasma generating container 31 to generate capacitively coupled plasma. Here, E×B drift is generated by the loop-shaped magnetic field B formed by the coil 36, and electrons in the plasma are concentrated in the plasma space. As a result, the plasma generated in the plasma generating container 31 has a high density.

The high-density plasma generated in the plasma generating container 31 is guided downward from the holes 38, and reaches the processing space S of the chamber 10 through the plasma flow paths 41 and the shower head 42 constituting the plasma introduction section 40. Then, a plasma processing is performed on the substrate W.

Here, ions may be suppressed by colliding with the inner walls of the flow paths while passing through the plasma flow paths 41 and the discharge holes 44 of the shower head 42. Thus, high-density plasma mainly composed of radicals is supplied to the substrate W, and the substrate W is subjected to a highly efficient plasma processing with little damage.

Also, in the present embodiment, while the loop-shaped magnetic field formed by the coil 36 is maintained, the radio-frequency power source 35 may be turned ON/OFF so that the plasma in the plasma generating container 31 may be turned ON/OFF. Therefore, the plasma has a high density due to the use of the magnetic field, and can be turned ON/OFF at a high speed.

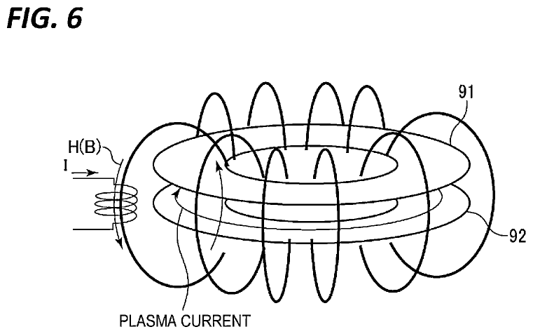

Patent Document 1 discloses generating high-density plasma by a toroidal loop using magnetism, but in the case of the toroidal loop, the plasma is formed by using magnetism. FIG. 6 is a view illustrating the technology of Patent Document 1 corresponding to the remote plasma source of the present embodiment. As illustrated in FIG. 6, a magnetic field H (magnetic field B) is generated in a circular motion around a pair of annular yokes 91 and 92 so that an induced current is generated in a circular shape between the yokes 91 and 92. This becomes a plasma current and a toroidal loop (toroidal plasma) is formed. When plasma is generated by the magnetic field in this way, it is difficult to turn ON/OFF plasma at a high speed.

In contrast, in the case of the present embodiment, the plasma has a high density due to the use of the magnetic field, and the plasma in the plasma generating container 31 can be turned ON/OFF at a high speed by turning ON/OFF the radio-frequency power source 35.

By utilizing this, it is possible to perform a process in which plasma is generated by the remote plasma source 30 as described above, and the generated plasma is introduced into the chamber 10 to perform a plasma processing on the substrate W, and a process in which in a state where plasma is turned OFF, a processing gas is supplied to the chamber 10 to perform processing on the substrate W without using plasma. Then, these processes may be repeatedly performed by turning ON/OFF the high-density remote plasma at a high speed. For example, as processing using plasma that is turned ON/OFF at a high speed, the PEALD may be exemplified.

When PEALD is performed using the plasma processing apparatus 100 of the present embodiment, for example, PEALD may be performed as follows. That is, a process, in which in a state where the radio-frequency power source 35 is turned OFF and plasma is turned OFF, a raw material gas is introduced into the processing space S and is adsorbed on the substrate W, and a process, in which plasma generated by the remote plasma source 30 is introduced to the processing space S and is reacted with the raw material gas adsorbed on the substrate to form a film, are repeatedly performed with purging of the chamber in between. When the raw material gas is reacted with the plasma, a reactive gas may be introduced from the gas supply unit 34, as a processing gas in addition to the plasma gas.

In order to implement the PEALD, an appropriate pressure is 500 mTorr (66.5 Pa) or more, and the plasma to be used is limited to the capacitively coupled plasma due to the reactivity and residence time of the raw material gas and reactive gas to be used. In the PEALD, although it is suitable to use high-density plasma mainly composed of radicals, a technique for not only applying high-frequency power, but also maintaining the generated capacitively-coupled plasma at a high density is required in order to more efficiently generate radicals.

In the present embodiment, in generating remote plasma using capacitively coupled plasma, an annular magnetic field is formed between a pair of electrodes to concentrate electrons in the plasma space. Thus, the generated capacitively-coupled plasma can be maintained at a high density. This is suitable for the PEALD.

Also, according to the present embodiment, the plasma generating container 31 of the remote plasma source 30 is disposed at a position close to the chamber 10 where the substrate W that is a processing target is disposed. Thus, radicals can be efficiently supplied to the processing space of the chamber 10 from the plasma generated in the plasma generating container 31.

Although embodiments have been described above, the embodiments disclosed herein should be considered to be illustrative and not restrictive in all aspects. The above embodiments may be omitted, replaced, or modified in various forms without departing from the scope and spirit of the appended claims.

For example, in the above description of the embodiment, the PEALD is used as an example of the plasma processing in which plasma is switched ON/OFF, but the present disclosure is not limited thereto. Also, in the above embodiment, a plasma introduction section having a plasma flow path and a shower head is exemplified but the plasma introduction section may have a structure in which the shower head is not used. Also, in the above embodiment, a case where radicals are mainly supplied to the processing space S is exemplified, but ions may also be supplied to the processing space S to achieve efficiency such as promoting etching of the substrate.

### DESCRIPTION OF SYMBOLS

| | |
|---|---|
| 10: chamber | 11: exhaust device |
| 20: substrate support | 30: remote plasma source |
| 31: plasma generating container | 32: first electrode |
| 33: second electrode | 34: gas supply unit |
| 35: radio-frequency power source | 36: coil |
| 40: plasma introduction section | 41: plasma flow path |
| 42: shower head | 50: controller |
| 100: plasma processing apparatus | W: substrate |
| S: processing space | |

1. A plasma processing apparatus comprising:
a chamber;
a substrate support provided within the chamber and configured to support a substrate;
a remote plasma source provided outside the chamber and configured to generate remote plasma; and
a plasma introduction section configured to introduce the remote plasma generated by the remote plasma source, into the chamber,
wherein the remote plasma source includes:
a plasma generating container having an annular space in which plasma is generated;
a gas supply that supplies gas to the plasma generating container;
a pair of electrodes facing each other and annularly provided along the annular space of the plasma generating container;
a radio-frequency power source capable of being turned ON/OFF to form a radio-frequency electric field between the pair of electrodes; and
a coil that is spirally provided around the plasma generating container and is supplied with a radio-frequency current, thereby forming a loop-shaped magnetic field between the pair of electrodes.

2. The plasma processing apparatus according to claim 1, wherein the radio-frequency power source is turned ON to generate plasma between the pair of electrodes in a state where a plasma gas is supplied from the gas supply to the plasma generating container and the loop-shaped magnetic field is formed by the coil between the pair of electrodes, and
the generated plasma is introduced into the chamber, thereby performing a plasma processing on the substrate.

3. The plasma processing apparatus according to claim 1, wherein the plasma generating container is provided at a position close to the chamber above the chamber.

4. The plasma processing apparatus according to claim 3, wherein the plasma introduction section includes:
a plasma flow path that guides the plasma from the plasma generating container toward the chamber; and
a shower head that discharges the plasma guided by the plasma flow path, into the chamber.

5. The plasma processing apparatus according to claim 4, wherein the plasma flow path is connected to a hole formed in a bottom or side of the plasma generating container.

6. The plasma processing apparatus according to claim 5, wherein the pair of electrodes includes an upper electrode and a lower electrode, and the lower electrode is formed of punched metal.

7. The plasma processing apparatus according to claim 1, wherein while the loop-shaped magnetic field formed by the coil is maintained, the radio-frequency power source is turned ON/OFF at a high speed so that the plasma in the plasma generating container is turned ON/OFF at a high speed.

8. The plasma processing apparatus according to claim 7, wherein the plasma in the plasma generating container is turned ON/OFF at a high speed to perform a plasma enhanced atomic layer deposition (PEALD) in the chamber.

9. The plasma processing apparatus according to claim 1, wherein a frequency of the radio-frequency power source is 450 kHz to 60 MHz, and a strength of the loop-shaped magnetic field is 30 G or more.

10. A plasma processing method comprising:
providing a plasma processing apparatus including: a chamber; a substrate support provided within the chamber and configured to support a substrate; a remote plasma source provided outside the chamber and configured to generate remote plasma; and a plasma introduction section configured to introduce the remote plasma generated by the remote plasma source, into the chamber,
wherein the remote plasma source including:
a plasma generating container having an annular space in which plasma is generated;
a gas supply that supplies gas to the plasma generating container;
a pair of facing electrodes annularly provided along the annular space of the plasma generating container;
a radio-frequency power source capable of being turned ON/OFF to form a radio-frequency electric field between the pair of electrodes; and
a coil that is spirally provided around the plasma generating container and is supplied with a radio-frequency current, thereby forming a loop-shaped magnetic field between the pair of electrodes; and
performing a processing on the substrate with plasma by turning ON the radio-frequency power source to generate plasma between the pair of electrodes in a state where a plasma gas is supplied from the gas supply to the plasma generating container and the loop-shaped magnetic field is formed by the coil between the pair of electrodes, and then introducing the generated plasma into the chamber.

11. The plasma processing method according to claim 10, further comprising:
performing a processing on the substrate without plasma by supplying a processing gas to the chamber in a state where plasma is turned OFF in the plasma generating container by turning OFF the radio-frequency power source.

12. The plasma processing method according to claim 11, wherein while the loop-shaped magnetic field formed by the coil is maintained, the radio-frequency power source is turned ON/OFF at a high speed so that the plasma in the plasma generating container is turned ON/OFF at a high speed to alternately repeat performing the processing without the plasma and performing the processing with the plasma.

13. The plasma processing method according to claim 12, wherein in the processing without the plasma, a raw material gas is supplied as a processing gas and adsorbed on the substrate, and in the processing with the plasma, the raw material gas adsorbed on the substrate is reacted to form a film, and
the PEALD is performed by alternately repeating performing the processing without the plasma and performing the processing with the plasma.

14. A remote plasma source that introduces plasma for performing a plasma processing on a substrate, into a chamber where the substrate is disposed, the remote plasma source comprising:
a plasma generating container having an annular space in which plasma is generated;
a gas supply that supplies gas to the plasma generating container;
a pair of electrodes facing each other and annularly provided along the annular space of the plasma generating container;
a radio-frequency power source capable of being turned ON/OFF to form a radio-frequency electric field between the pair of electrodes; and
a coil that is spirally provided around the plasma generating container and is supplied with a radio-frequency current, thereby forming a loop-shaped magnetic field between the pair of electrodes.

15. The remote plasma source according to claim 14, wherein the radio-frequency power source is turned ON to generate plasma between the pair of electrodes in a state where a plasma gas is supplied from the gas supply to the plasma generating container, and the loop-shaped magnetic field is formed by the coil between the pair of electrodes.

16. The remote plasma source according to claim 14, wherein the plasma generating container is provided at a position close to the chamber above the chamber.

17. The remote plasma source according to claim 16, wherein the plasma is introduced into the chamber through a hole formed in a bottom or side of the plasma generating container.

18. The remote plasma source according to claim 17, wherein the pair of electrodes has an upper electrode and a lower electrode, and the lower electrode is formed of punched metal.

19. The remote plasma source according to claim 14, wherein while the loop-shaped magnetic field formed by the coil is maintained, the radio-frequency power source is turned ON/OFF at a high speed so that the plasma in the plasma generating container is turned ON/OFF at a high speed.
